(19) United States
(12) Patent Application Publication
(10) Pub. No.: US 2025/0081671 A1
(43) Pub. Date: Mar. 6, 2025

(54) METHODOLOGY FOR INCREASE OF BRIGHTNESS OF LIGHT PRODUCED BY A NANOSCALE SEMICONDUCTOR-BASED HETEROSTRUCTURE

(71) Applicant: UNIVERSITY OF SOUTH FLORIDA, Tampa, FL (US)

(72) Inventor: Dmitri V. Voronine, Tampa, FL (US)

(21) Appl. No.: 18/620,133

(22) Filed: Mar. 28, 2024

Related U.S. Application Data
(60) Provisional application No. 63/492,833, filed on Mar. 29, 2023.

(51) Int. Cl. H01L 33/00; G02B 5/00; H01L 33/50

(52) U.S. Cl. CPC H10H 20/811; G02B 5/008; H10H 20/8512

(57) ABSTRACT

An apparatus configured to increase photoluminescence, generated by a substantially monolayer 2D heterostructure having a heterojunction, by at least several orders of magnitude. A method for use of same in the regime when such heterojunction is placed between pieces of a plasmonic material with a sub-nanometer distance therebetween.

### CROSS REFERENCE TO RELATED APPLICATIONS

This US patent application claims the benefit of and priority from the U.S. provisional patent application No. 63/492,833 filed on Mar. 29, 2023, the entire contents of which are incorporated by reference herein.

### TECHNICAL FIELD

The present invention relates to two-dimensional heterostructures and optoelectronic devices utilizing such heterostructures and, more particularly, to a methodology of operating of a heterostructure (dimensioned as a substantially monolayer heterostructure) in a specific material environment configured to increase the capacity of such heterostructure to produce light output by at least several orders of magnitude—as compared with the situation when such specific material environment is not employed.

### RELATED ART

Lateral 2D heterostructures (and, in particular, two-dimensional—2D—heterostructures employing transition metal dichalcogenides, or TMDs) have been investigated due to the exceptional properties of their atomically sharp junctions, quantum confinement, and band gap tunability. Notwithstanding, because of the high degree of spatial averaging of measurements of the far-field optical characterization—such as that used during the conventional photoluminescence (PL) spectroscopy—there is a need to improve the understanding of operation of the heterojunctions at the nanoscale in order to expand their use in practical applications. Experimentally speaking, such improvement remains rather challenging since—as is well known in related art—the PL signals from the atomically thin junctions are weak (the capability of the material(s) forming the heterojunctions to generate light is continually reduced with the reduction of the thickness of the heterojunction—as the thickness of the material(s) is reduced from that of a bulk material to that representing a 2D material) and the materials surrounding the heterojunction generate large background that causes the unnecessary noise. Several nano-optical imaging techniques were used to address this challenge—including scanning near-field optical microscopy (SNOM; see, for example, Lee, Y. et al., in Nanoscale, 2015, 7(28), 11909-11914), tip-enhanced Raman spectroscopy (TERS; see, for example, Lee, C. et al., in Scientific Reports, 2017, 7(1), 1-7)), and tip-enhanced photoluminescence (TEPL; see, for example, He, Z. et al., in Science advance, 2019, 5(10) eaau8763). The spatial imaging resolution achievable with the use of these techniques depends on the size of the spot of excitation energy and the signal enhancement. The excitation spot size is limited by the size of the scanning local probe such as the plasmonic metallic tip, which is typically on the order of 10 nm. The signal enhancement is limited by the electric field strength at the tip apex, which depends on tip-sample distance (TSD). Classically, the PL signal increases with the decrease of the TSD (see, for example, Novotny, L. et al., Principles of Nano-Optics, Cabridge University Press, 2012). However, for the TSD shorter than about 1 nm, the PL signal necessarily decreases due to charge tunnelling between the tip and the sample, thereby leading to the depletion of surface charge density, described using the quantum plasmonics mode (see, for example, Esteban, R. et al., in Nature Communications, 2012, 3(1), 1-9); or Chang, Y. et al. in Scientific Reports, 2016, 6(1), 1-9).

There remains an unsatisfied need in devising an approach enabling two-dimensional heterostructures—which are becoming increasingly important for construction of spatially-minimized optoelectronic devices—to generate amounts of light that are otherwise would not be supported by such heterostructures.

### SUMMARY OF THE INVENTION

Implementations of the idea of the invention aim at a formation and used of a 2D heterojunction configured to operate in a plasmonic environment and resonantly in order to enhance/increase (in some cases—by orders of magnitude) the ability of such heterojunction to generate light. Accordingly, embodiments of the invention provide an article of manufacture that includes a substantially monolayer lateral 2D heterostructure formed by first and second monolayer materials and having a 2D lateral heterojunction; a first piece of a plasmonic material positioned at such heterojunction on one side of the heterostructure and a second piece of the plasmonic material positioned at such heterojunction on the other side of the heterostructure such as to be separated from one another by a distance substantially not exceeding 10 nanometers (preferably, not exceeding 1 nanometer; most preferably—by a distance shorter than 1 nm, that is by a pico-scale distance); and a source of excitation energy that is configured to deliver the excitation energy to the 2D lateral heterojunction and to excite such heterojunction in resonance with an energy transition of each of the monolayer materials.

In at least one case the article may be judiciously configured as a source of light that is configured to generate first light with a first optical spectrum and second light with a second optical spectrum (the first optical spectrum representing a spectrum of photoluminescence of the first monolayer material and the second optical spectrum representing a spectrum of photoluminescence of the second monolayer material). Alternatively or in addition—and substantially in each implementation—the article may include a detection system containing a detector and a spectral filter (the latter being configured to substantially block excitation energy that has been produced by the source of excitation energy while, at the same time, to transmit first energy and second energy that are generated, respectively, at the first and second monolayer materials within the heterojunction when such heterojunction is irradiated with the excitation energy). Alternatively or in addition—and substantially in every implementation—the article may satisfy at least one of the following conditions: (a) to have a first cross-section (of the first piece of the plasmonic material across an axis normal to a surface of the heterojunction) that substantially does not exceed a width of the heterojunction; (b) to have a second cross-section (of the second piece of the plasmonic material across the axis) that does not exceed such width; (c) to have the first piece of the plasmonic material and/or the second piece of the plasmonic material deposited on a corresponding surface of the heterojunction; and (d) to have the first piece of the plasmonic material and/or the second piece of the plasmonic material dimensioned as a tip of a projecting object. Optionally, the source of excitation energy may be configured as an optical source—for example, include a source of laser light.

Embodiments of the invention additionally provide a method for generating light. Such method—performed with substantially every embodiment of the article of manufacture referred to above—includes a step of resonantly exciting at least the 2D lateral heterojunction of the substantially monolayer lateral 2D heterostructure with excitation energy produced by the source of excitation energy, and a step of generating first photoluminescent light at the 2D lateral heterojunction with the use of a tunneling-induced charge transfer plasmon mode of the plasmonic material. Optionally, in at least one specific case, the step of irradiating may include irradiating a portion of at least one of the first and second monolayer materials that is outside of the 2D lateral heterojunction, and a step of generating second photoluminescent light at such portion of the at least one of the first and second monolayer materials. Alternatively or in addition—and substantially in every implementation—the method may be complemented with (a) the step of substantially blocking the excitation energy from propagating from the heterostructure towards a chosen location while directing at least the first photoluminescent light to such chosen location; and/or with (b) the step of repositioning at least one of the first and second pieces of the plasmonic material along a surface of the substantially monolayer lateral 2D heterostructure to vary an irradiance of photoluminescent light generated at the heterostructure by at least one order of magnitude when the at least one of the first and second pieces is moved between the heterojunction and such area. (This latter step is performed when the area of the at least one of the first and second monolayer materials that is outside of the 2D lateral heterojunction is also irradiated with the excitation energy. Additionally, such repositioning step includes maintaining a distance, measured between the first and second pieces along a normal to a surface of the heterostructure, to remain substantially unchanged.)

Embodiments of the invention additionally provide for a method that includes a step of increasing (by at least one order of magnitude) a first amount of first photoluminescent light (that is generated at a 2D lateral heterojunction of a substantially monolayer lateral 2D heterostructure formed by first and second monolayer materials). Such increase is carried out by at least sandwiching the 2D lateral heterojunction first piece of a plasmonic material (positioned at cush heterojunction on one side of the heterostructure) and a second piece of the plasmonic material (positioned at the heterojunction on the other side of the heterostructure) such as to have a distance, separating the first and second pieces along a normal to a surface of the heterostructure to substantially not exceed 1 nanometer, followed by irradiating at least the 2D lateral heterojunction with light to excite each of the monolayer materials in the necessarily resonant fashion. The determination of increasing is carried out in comparison with a second amount of second photoluminescent light generated at the same heterojunction that is not sandwiched between the first and second pieces of a plasmonic material.

Embodiments additionally provide a method that includes a process of increasing (by at least one order of magnitude) a first amount of first photoluminescent light (that is generated at a 2D lateral heterojunction of a substantially monolayer lateral 2D heterostructure formed by first and second monolayer materials). The process of increasing is effectuated by (i) sandwiching the 2D lateral heterojunction first piece of a plasmonic material positioned at such heterojunction on one side of the heterostructure and a second piece of the plasmonic material positioned at such heterojunction on the other side of the heterostructure to have a distance, separating the first and second pieces along a normal to a surface of the heterostructure to substantially not exceed 1 nanometer (or, preferably, be a pico-distance) and (ii) irradiating at least the 2D lateral heterojunction with light to excite each of the monolayer materials necessarily resonantly. The determination of increasing is carried out in comparison with a second amount of second photoluminescent light generated at the same heterojunction that is not sandwiched between the first and second pieces of a plasmonic material.

### BRIEF DESCRIPTION OF THE DRAWINGS

The invention will be more fully understood by referring to the following Detailed Description of Specific Embodiments in conjunction with the Drawings, of which:

FIG. 1A is a schematic illustration of a tip-sample distance (TSD) dependent photoluminescence (PL) measurements of a lateral WS₂—MoS₂ lateral heterostructure in the classical (TSD>0.36 nm) and quantum (TSD<0.36 nm) regimes. Electric field excitation spots (ovals, 114) decrease with the decrease of the TSD;

FIG. 1B presents a schematic energy level diagram of the 2D lateral heterojunction, showing hot electron injection (HEI) from the plasmonic tip to the heterostructure accompanied by the non-resonant (γ₁, arrow 120) and resonant (γ₂y2, curved arrow 122) charge transfer;

FIG. 1C illustrates the pip-sample configuration in the considered example of a tip-enhanced photoluminescence (TEPL) experiment. Inset shows an atomic-force phase image of a part of the used 2D heterostructure including the WS₂—MoS₂ heterojunction at locations 1, 2, w . . . 9 (also marked with corresponding stars) during the TSD measurement;

FIG. 1D provides a sketch of the PL signals of WS₂ (shaded area 130) and MoS₃ (shaded smaller area 132) including the laser central wavelength (solid line 134) and the filter cutoff wavelength (dashed line 136);

FIG. 1E is a schematic diagram of the PL enhancement mechanism in a quantum plasmonic p-n junction;

FIG. 2 includes multiple graph-windows organized into three columns. The first column C1, representing the spectral distribution of the TSD-dependent PL signal, contains graph windows marked a, b, c, d, and e. Here, presented are 2D contour plots of PL signals at various TSDs for locations S1, S2, S3, S4, and 5 across the 2D heterojunction, schematically marked with stars in the inset. The second column C2, shown enhancement factors in a classical regime, contains graph-windows f, g, h, i, and j. Vertical solid and dashed lines in graph-window h indicate the van der Waals contact and jump-to-contact TSDs, respectively. The third column C3, containing graph-windows k, l, m, n, and o, presents PL spectra at the respectively-corresponding locations S1, S2, S3, S4, and S5 across the 2D heterojunction. Here, PL spectral intensities are shown at 20 nm (plots A) and 0.32 nm (plots B) TSDs. The shaded area in the graph-window k represents the spectral range of the integrated TSD signal;

FIG. 3 includes two columns I and II of graph-windows and illustrates the picoscale TSD dependent PL of the WS₂—MoS₂ 2D lateral heterostructure in the quantum tunneling regime. Graph-windows a, b, c, d, and e of column I present 2D contour plots and graph-windows f, g, h, i, and j of column II illustrate quantum enhancement factors for the locations S1 through S5 across the 2D lateral heterojunction (as marked in FIG. 2);

FIG. 4A contains graph-windows marked a, b, c, d. FIG. 4B contains graph-windows marked e, f g, h. FIGS. 4A and 4B, respectively, illustrate simulated classical and quantum TSD-dependent PL enhancement factors of WS₂— MoS₂ 2D lateral heterostructure for various values of the non-resonant (γ₁) and resonant (γ₂) charge transfer coefficients. The PL signals for γ₁=γ₂=0 correspond to the pure MoS₂ (graph-windows a, e) and WS₂ (graph-windows b, f) materials, located outside of the area/width of the 2D lateral heterojunction. The PL signals for γ₁, =0.25 correspond to the WS₂—MoS₂ heterojunction itself (graph-windows c, d, g, h).

Generally, the sizes and relative scales of elements in Drawings may be set to be different from actual ones to appropriately facilitate simplicity, clarity, and understanding of the Drawings. For the same reason, not all elements present in one Drawing may necessarily be shown in another.

### DETAILED DESCRIPTION

### General

In accordance with preferred embodiments of the present invention, plasmonic-based methods and apparatus are disclosed for enhancement of light generation at a 2D lateral heterojunction formed by a monolayer material which, as discussed below, under ordinary circumstances (that is, in absence of the proposed configuration) is capable of generating light only at levels or in the amounts substantially lower (in the considered specific empirical examples—up to 3 orders of magnitude lower) than the amounts of light achieved with the use of the proposed methodology.

A skilled person appreciates that quantum effects, such as tunneling and non-locality, play an important role in plasmonic systems when the TSD is reduced. The classical descriptions of surface plasmon energy, linewidth, and field enhancement break down, and the full quantum mechanical treatment is necessary (see, for example, Zuloaga, J. et al., in Nano letters 2009, 9 (2), 887-891; or Kravtsov, V. et al., in Nano letters 2014, 14 (9), 5270-5275).

In this quantum plasmonic regime, tunneling at small TSD leads to the reduction of surface charge density and the corresponding near field intensity. Therefore, after the optimal balance of electromagnetic enhancement and tunneling suppression, further reduction of TSD leads to the quenching of the TEPL signal. While several experimental demonstrations revealed this tunneling limit of SERS signals for gaps smaller than about 1 nm, the related art limited the investigation of these quantum plasmonic effects to substantially pure transition metal dichalcogenide (TMD) materials or the non-resonantly excited TMD heterostructures (as evidenced by, for example, Albagami, A. et al., in ACS Appl Mater Interfaces 2022, 14 (8), 11006-11015) and did not observe any particular enhancement of the light signal generated by such heterostructures. Considering the persisting need in generation of practically useful, large amount of PL light at the 2D heterostructures, the results available from related art beg a question of whether a completely different structural arrangement of a now-popular 2D heterostructure could, indeed, lead to the desired—and thus far, elusive—result.

This disclosure addresses this very question: according to the idea of the invention—and in stark contradistinction with the related art—it is the TSD dependence of the photoluminescence generated in resonantly excited monolayer material based heterostructures that operation of the embodiments of the invention turns on.

The implementations of the idea of the invention were investigated with a 2D TMD system, namely, a WS₂—MoS₂ monolayer lateral heterostructure placed in a plasmonic cavity formed by an Au-tip and an atomically thin Au substrate. Measurements of the picometer-scale controlled TSD-dependent PL with the use a 660 nm laser excitation were performed in resonance with the A excitons of the heterostructure. The experiments were carried out at several spatial locations across the junction in the classical (320 pm<TSD<20 nm) and quantum tunnelling (220 pm<TSD<320 pm) regimes.

The skilled artisan having the advantage of this disclosure will readily appreciate that while specific embodiments of the invention are illustrated with the very specific example(s)—specifically, the examples including a lateral monolayer WS₂—MoS₂ heterostructure placed in a “picocavity” formed from the specifically shaped Au-pieces and using sub-diffraction limited tip-enhanced photoluminescence (TEPL) spectroscopy with sub-nanometer tip-sample distance control—such illustrations are but examples only.

Generally, the proposed methodology and approach pertain to addressing a well-known in related art inevitable reduction of the ability of a heterojunction to generate light as the thickness of the material forming such heterojunction is reduced from the “bulk thickness” to the substantially 2D thickness (represented, in practice, by a monolayer of such material) by situating the target monolayer material forming the substantially monolayer 2D lateral heterostructure between first and second pieces of a chosen plasmonic material and, while exciting such system (and, particularly, the 2D lateral heterojunction) resonantly, achieving a rather unexpectedly large (up to three orders of magnitude in the discussed examples) enhancement of a PL signal.

For the purposes of this disclosure and the appended claims, the term “a monolayer material” is defined as a material that is (i) chosen from a 2D semiconductor material, a 2D transition metal dichalcogenide material (such as that used in examples of embodiments discussed herein), and a 2D material composed as MX₂ (where M is a transition metal such as Mo, W, Re, for example, and S is a chalcogen such as S, Se, Te, for example) and that is (ii) dimensioned substantially as a monolayer, as understood in related art. (While not necessarily preferred, in one specific implementation, a chosen monolayer material may optionally have a thickness that is slightly greater than that of a monolayer—for example, be dimensioned to include two monolayers of the material at hand.)

Similarly, the term “plasmonic material” refers to and is defined as a metal or metal-like material exhibiting negative real permittivity. Examples are provide by Au, Ag, Al, Cu, and WO₃ with oxygen vacancies. The terms “resonance”, “resonantly” and similar terms are defined—with respect to the spectral parameter that is being discussed—as a frequency (of an identified energy) that is substantially equal to a resonant frequency of a tunneling-induced change transfer plasmon of the plasmonic material.

Below, a theoretical model of the quantum plasmonic 2D heterojunction is presented, where tunneling of hot electrons between the plasmonic material (shaped, in the discussed specific examples as an Au tip) and a component of the monolayer material forming the heterojunction (in the discussed specific examples—MoS₂) leads to the quenching of the MoS₂ PL, while simultaneously increasing the photoluminescence produced by the other component of the monolayer material (in the examples—WS₂), in stark contradistinction to the non-resonant reverse transfer conventionally considered in related art. Phrased differently, the proposed approach allows for a large increase of PL in the regime of sub-nanometer scale plasmonic-material-to-monolayer-material distance at the location of the 2D lateral heterojunction. The enhancement to the interplay of the quantum plasmonic and chemical charge transfer mechanisms in the coupled 2D monolayer materials in a plasmonic “picocavity” formed by the first and second pieces of the plasmonic material that sandwich the heterojunction in-between. The simulations show good agreement with the experiments, revealing a range of parameters and enhancement factors corresponding to the switching between the classical and quantum regimes. The controllable photo-response of the substantially monolayer 2D heterojunction in the proposed system lends itself to use of such configuration in novel nanodevices.

Overall, the problem persisting in related art and manifesting in inevitable reduction of the ability of an appropriately chosen target material to emit light (which reduction necessarily accompanies the reduction of a thickness of such material upon a transition from a “bulk” version of the material towards a “2D” version of the material) is solved by devising a specific material combination in which a substantially monolayer 2D heterojunction (of a chosen 2D heterostructure, formed with the use of the target material) is complemented with and sandwiched between pieces of a plasmonic material that are separated from one another by a distance substantially not exceeding 10 nm, preferably not exceeding a few nanometers, and most preferably not exceeding or even shorter than 1 nm. Under the condition of resonant excitation of the target material that forms such heterojunction, the generation of a tunneling-induced charge transfer plasmon (CTP) mode of the plasmonic material facilitates the increase of the amount of light—emitted at the substantially monolayer 2D heterojunction—typically by several orders of magnitude as compared with the situation when the heterojunction is not complemented with the plasmonic material.

The disclosure of the publication titled “Quantum plasmonic two-dimensional WS₂—MoS₂ heterojunction, authored by Ambardar, S. et al. in Nanoscale, 2023, 15, 7318, is incorporated by reference herein in its entirety.

### Materials, Methods, and Experimental Setup.

Substantially monolayer lateral WS₂—MoS₂ heterostructures were grown on a SiO₂/Si substrate in a quartz tube using a one-pot chemical vapor deposition (CVD) system (see, for example, Sahoo, P. K. et al., in Nature 2018, 553 (7686), 63-67). The heterostructures were then transferred to an atomically flat Au substrate (TedPella) using a PMMA-assisted liquid transfer method. The substantially monolayer thickness of 2D heterostructures was confirmed by the atomic force and Raman measurements (not shown; as previously described by, for example, Ambardar, S. et al. in Nanoscale 2022, 14 (22), 8050-8059). Here, Raman characterization measurements were performed using 532 nm excitation. The observed Raman intensity of the MoS₂ in-plane E¹_{2g} vibrational mode at 385 cm⁻¹ was in agreement with the previously reported monolayer MoS₂. Similarly, the vibrational mode at 355 cm⁻¹ confirmed the presence of monolayer WS₂. The atomic force height profiles showed an average monolayer thickness of about 0.9 nm.

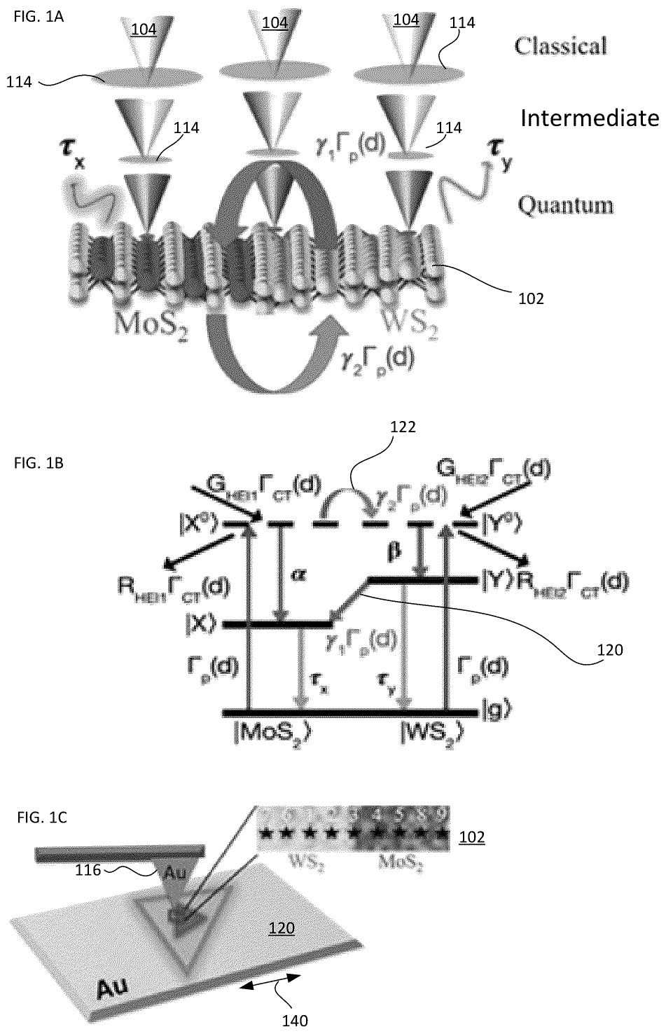

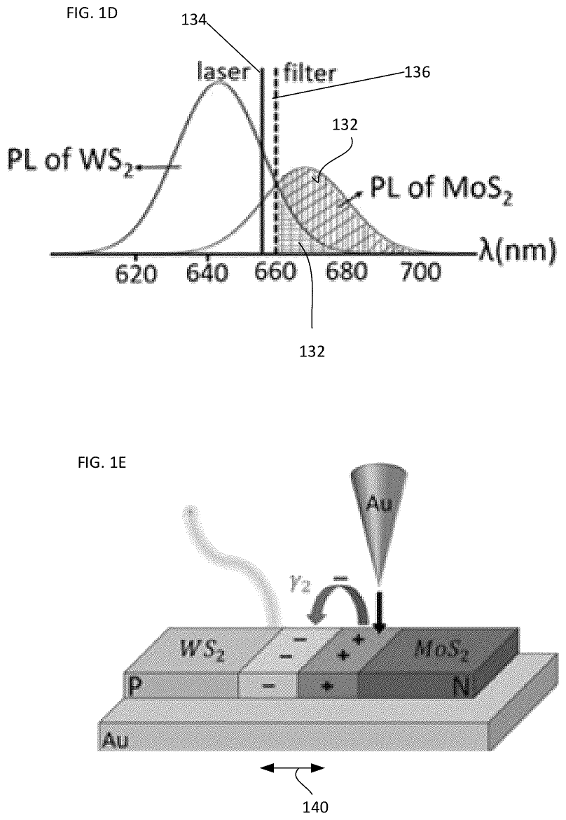

Atomic force microscopy (AFM), PL and TEPL imaging measurements of such structure were performed using a confocal optical microscope (Lab am Evolution, Horiba) coupled to a scanning probe microscope (OmegaScope, Horiba) as described by, for example, Zhang, Y. et al., in Scientific reports 2016, 6 (1), 1-9. FIGS. 1A, 1B, 1C, 1D, and 1E schematically illustrate the used experimental setup and provide schematic diagrams illustrating the empirically acquired PL output.

FIG. 1A shows a schematic of a monolayer material of WS₂—MoS₂ 102 forming a 2D heterojunction while showing the Au-tip 104 at different locations in the same figure: at the MoS₂ portion of the monolayer material outside of the heterojunction (in the left-hand-side of FIG. 1A), at the WS₂ portion of the monolayer material outside of the heterojunction (on the right of FIG. 1A), and substantially at the center of the WS₂—MoS₂ heterojunction itself (middle of FIG. 1A). A corresponding Au-tips at different TSDs is shown at each of these lateral locations. These TSDs correspond to the non-contact (large TSD>1 nm), van der Waals (vdW) contact (medium TSD of about 0.36 nm), and conductive contact (small TSD shorter than 0.22 nm). Quantum tunneling takes place at TSD smaller than the vdW contact distance (which situation referred to as the quantum regime). The large TSD range is referred to as the classical regime. The spatial resolution of the PL imaging in the classical regime is given by the far-field excitation spot size with the radius of about 500 nm shown by the oval 114. The spatial resolution in the quantum regime is given by the size of the single gold atom at the Au-tip apex. The spatial resolution in the intermediate regime is given by the near-field excitation spot size based on the 10 nm radius of the Au-tip apex.

The sketch of the TEPL setup in FIG. 1C illustrates the plasmonic Au-containing tip 116 on top of the substantially monolayer 2D WS₂—MoS₂ heterostructure 102 that has been placed on the atomically flat Au substrate 120. The area of the 2D heterostructure used for TEPL measurements included parts of the heterostructure containing pure WS₂ and pure MoS₂ (that is, portions of the heterostruction are outside the heterojunction) and the WS₂—MoS₂ heterojunction itself. The inset of FIG. 1C shows the atomic force phase image with marked locations of TSD measurements labeled 1 through 9, where spot 3 is located right at the heterojunction. Locations at representative spots 1 through 5 were chosen for the analysis discussed. (Notably, measurements at other locations farther away from the heterojunction showed behavior similar to that discussed below that is characteristic to the pure WS₂ and MoS₂ materials.) The distances between the spots 1-2, 2-3, 3-4, and 4-5 were, respectively, 172 nm, 246 nm, 238 nm, and 231 nm.

The 660 nm (or, in a related embodiment, 532 nm) beams of linearly polarized laser excitation light were focused on the tip apex of the Au-coated Ag tip with the tip apex radius of about 10 nm at the approximately 530 angle of incidence (not shown in FIGS. 1A-1E) to excite the heterostructure resonantly. The radius of the laser focal spot was about 500 nm. The emitted PL signals were collected using the same objective (100×, A 0.7, f=200; not shown). Here—as referred to in FIG. 1D—the additional 665 nm cutoff spectral filter (line 132) was used to substantially block the laser-excitation background signal (line 134) from reaching the optical detection system (not shown for simplicity of illustration). This resulted in the partial blocking of the WS₂ and MoS₂ PL signals as well.

Atomic force (AF) measurements (FIGS. 1C, 1E) were performed in the tapping mode with the 20 nm average TSD. TEPL measurements were performed in the AF contact mode. The angle between the optical axis of the incident laser beam and the horizontal sample plane was about 25°. The angle between the tip and the sample plane was about 78°. The vector of linear polarization of the incident light was oriented along the axis of the tip 116. The tip 116 of the AFM and the laser source of excitation energy were kept stationary during the experiments, while the sample stage (on which the substrate 120 carrying the heterostructure 102 was placed) was scanned, as illustrated with the arrow 140.

### Experimental Results.

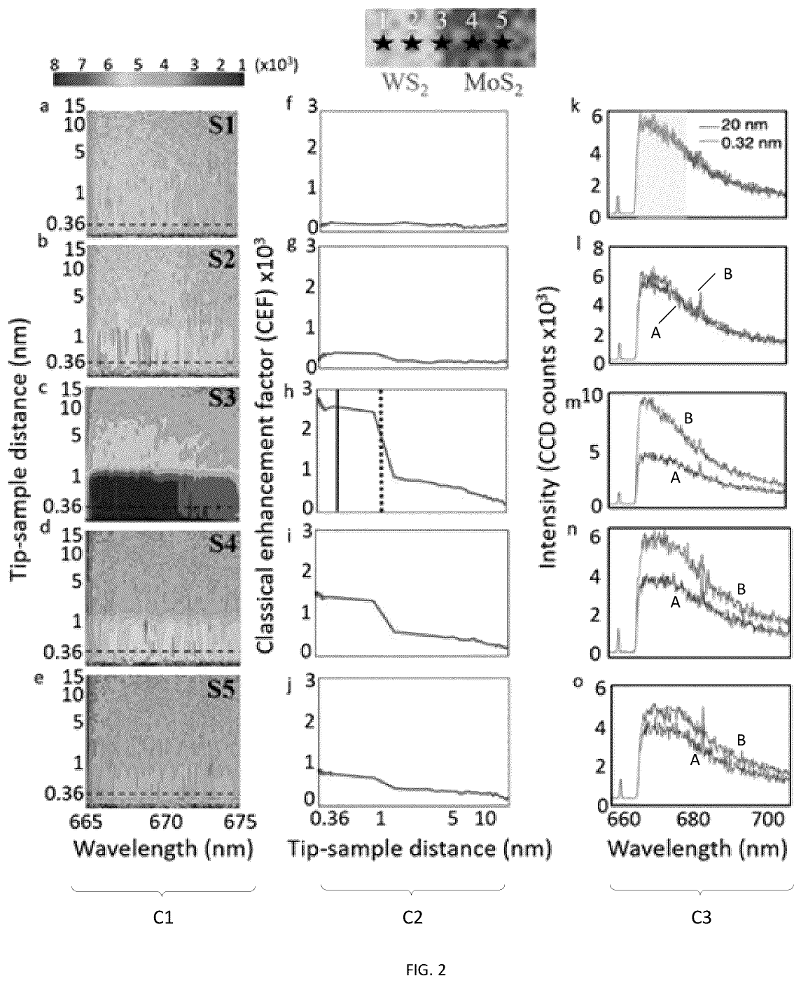

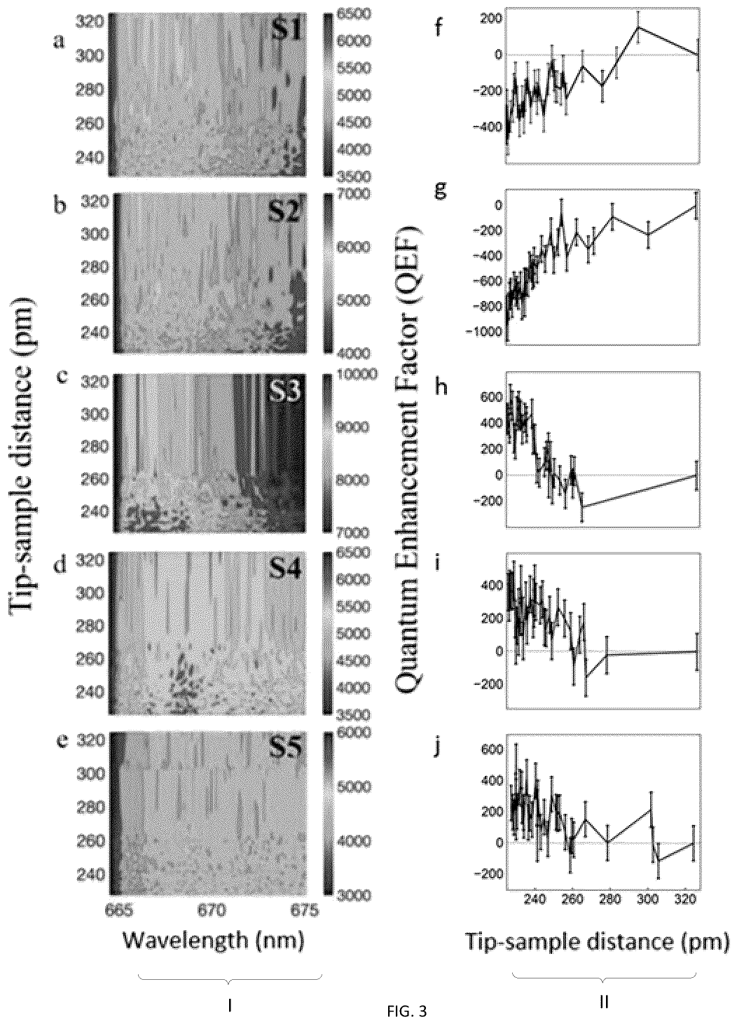

Results of the TSD-dependent measurements of the PL output from the heterostructure 102 at the locations S1, S2, S3, S3, S4, and S5 across the WS₂—MoS₂ 2D lateral heterojunction, obtained both in the classical and quantum regimes, are illustrated in FIGS. 2 and 3, respectively.

The 2D contour maps in graph-windows a through e of FIG. 2 show PL intensity as a function of TSD and wavelength of excitation light. The 2D contour plots were obtained by combining the PL signals at two TSD regimes, separated by the horizontal dashed lines (indicated in each of the graph-windows a through e). The TSD analysis procedure used the TSD of about 0.36 nm as a reference point, which corresponded to the vdW contact distance between the Au atom at the Au-tip 116 and the S atom of the WS₂—MoS₂ heterostructure 102. The piezo motor referenced positions were used to assess the TSD values in the classical regime (above the horizontal dashed lines indicated in each of the graph-windows a through e). The TSD values in the quantum regime (below these dashed lines) were obtained using the previously described fitting procedure in the repulsive range of the Lennard-Jones potential (see Zhang, Y. et al., in Scientific reports 2016, 6 (1), 1-9). Briefly, the tip and laser were kept stationary before the vdW contact, while the sample stage carrying the combination of the substrate and the substantially monolayer heterostructure 102 moved upwards. After the vdW contact, both the tip and sample moved upwards together, while the AF cantilever bending and the tip-sample repulsive force increased. The corresponding TSD values were obtained by fitting the repulsive force as a function of the piezo position. The value of the A coefficient was set to A=2.2×10⁻⁷, in the repulsive force, F=A/d, and the cantilever spring constant was set to of 2.8 N/m.

The classical and quantum enhancement factors, shown in FIGS. 2 and 3, respectively, were calculated to provide quantitative analysis of the PL enhancement normalized by the contributing areas in the classical and quantum regimes. To this end, the conventional definition of the classical enhancement factor (CEF) was used:

$$CEF = ( \frac{{I}_{Tip In}}{{I}_{Tip Out}} - 1 ) \frac{{S}_{FF}}{{S}_{NF}} \qquad ( 1 )$$

where I_{Tip In} and I_{Tip Out} are the PL intensities with the tip 116 being in contact and out of contact with the sample 102, respectively. S_{NF} and S_{FF} are the effective surface areas that generate the near-field (NF) and far-field (FF) PL signals, respectively. It was assumed that the NF PL at vdW contact is generated by the tip apex with the 10 nm radius of curvature. On the other hand, the radius of the FF excitation laser spot was about 500 nm. Assuming circular areas of πR² for both cases results in the value of S_{FF}/S_{NF} of about 2.5×10³. The resulting CEF values as a function of TSD are shown for the locations S1 through S5 in graph-windows f through j of FIG. 2, respectively.

In the quantum plasmonic regime, the tunneling effect was considered by using the NF PL intensity at vdW contact TSD of 0.36 nm for I_{vdW}, relative to the NF PL at TSD<0.32 nm for contact intensity I_{C}, which approaches the conductive contact distance of 0.22 nm. The corresponding quantum EF (QEF) equation is:

$$QEF = ( \frac{{I}_{C}}{{I}_{vdW}} - 1 ) \frac{{S}_{vdW}}{{S}_{C}} . \qquad ( 2 )$$

It was assumed that the PL enhancement at TSD<0.36 nm originated from only a few atoms at the tip 116 apex (in the limit—from just one Au atom). Therefore, the radius of an Au atom of 0.179 nm was used to define the area normalization factor S_{C} (that corresponds to the effective area of tunnelling through a single atom of plasmonic material, Au). To determine S_{vdW} (the area normalization factor defined for TSD of about 0.36 nm that corresponds to can der Waals contact distance) we used the same area as above for the near field with the tip apex area of about 10 nm. This gave the value of the S_{vdW}/S_{C} factor of about 1.2×10⁴. The resulting QEF values as a function of TSD are shown for the locations S1-S5 in graph-windows f through j of FIG. 3, respectively.

By setting the S_{C} area to that of one single Au atom the highest estimate of QEF can be obtained. (This assessment is based on recent sub-nanometer resolution TERS and TEPL experiments, where a single Au or Ag atom protruding from a plasmonic tip was responsible for the signal enhancement; see for example Lee, J. et al., in Nature 2019, 568 (7750), 78-82, available at https://doi.org/10.1038/s41586-019-1059-9). The QEF will decrease by taking the low estimate of the tip apex area of 10 nm. However, the experimental results presented here better match the simulations that utilize the single Au atom area.

The CEF and QEF values corresponding to the locations S1-S5 across the heterojunction of the heterostructure 102 are compared in Table 1. The CEF value at TSD=0.32 nm provides the estimate of the relative PL enhancement due to the near field at the tip apex interacting with the various parts of the heterostructure. The largest enhancement of 2554 was obtained at the junction in spot S3. Less than 2 orders of magnitude enhancement was obtained in spot S1 on the pure WS₂. This may be attributed to the different enhancement mechanisms of the junction compared to the pure materials, as discussed below. Further suppression in spot S1 is observed in QEF by decreasing the TSD, with large negative values of QEF indicating the contribution of the traditional quantum plasmonic limit to the PL enhancement. On the other hand, at location S3 of the heterojunction, the QEF value is large and positive, indicating the additional three orders of magnitude PL enhancement by a further decrease of TSD by a hundred pm below the vdW contact. Positive QEF is also observed at locations S4 and S5 on pure oS₂ with lower values compared to the junction. This enhancement decreases when the tip moves away from the junction.

TABLE 1
Classical (CEF) and quantum (QEF) enhancement factors at
van der Waals contact (the TSD of about 0.32 nm) and at
conductive contact (the TSD distance of about 0.20 nm),
respectively, at locations S1-S5 across the heterostructure.

| Spots | CEF (0.32 nm) | QEF (0.20 nm) |
|---|---|---|
| S1 | 16 | −234 |
| S2 | 219 | −966 |
| S3 | 2554 | 445 |
| S4 | 1294 | 362 |
| S5 | 587 | 259 |

### Theoretical Model.

We used the phenomenological rate equation model to describe the interplay between hot electron injection and charge transfer across the 2D heterojunction that was observed in the experiments. FIG. 1B shows the schematic state diagram used to model the excited state dynamics of the WS₂—MoS₂ heterostructure 102. The diagram shows that the initial population of the electrons excited from the ground state, |g [symbol] , above the band gap to states |X⁰ [symbol] or |Y⁰ [symbol] , subsequently decays to exciton states |X [symbol] or |Y [symbol] . Here, )|X⁰ [symbol] , |X [symbol] and |Y⁰ [symbol] , |Y [symbol] , are the excited states of the MoS₂ and WS₂ portions of the heterostructure, respectively, which might include some degree of alloying due to the proximity to the heterojunction. As a result, the population dynamics can be described by the following rate equations:

$$\frac{{dN}_{g}}{dt} = - 2 {Γ}_{p} ( d ) {N}_{g} + \frac{{N}_{X}}{{τ}_{X}} + \frac{{N}_{Y}}{{τ}_{Y}} , \qquad ( 3 )$$

$$\frac{{dN}_{X}}{dt} = α {N}_{{X}^{0}} - \frac{{N}_{X}}{{τ}_{x}} + {γ}_{1} {Γ}_{p} ( d ) {N}_{Y} , \qquad ( 4 )$$

$$\frac{{dN}_{Y}}{dt} = β {N}_{{Y}^{0}} - \frac{{N}_{Y}}{{τ}_{y}} + {γ}_{1} {Γ}_{p} ( d ) {N}_{Y} , \qquad ( 5 )$$

$$\frac{{dN}_{{X}^{0}}}{dt} = {Γ}_{p} ( d ) {N}_{g} - α {N}_{{X}^{0}} - {γ}_{2} {Γ}_{p} ( d ) {N}_{{X}^{0}} , \qquad ( 6 )$$

$${N}_{g} + {N}_{X} + {N}_{Y} + {N}_{{X}^{0}} + {N}_{{Y}^{0}} = 1 , \qquad ( 7 )$$

where α=1 ps⁻¹ and β=15 ps⁻¹ are the exciton |X [symbol] and |Y [symbol] generation rates (see α and β arrows in FIG. 1B). The larger value of β as compared to that of α was used due to the stronger light-matter interaction of WS₂ compared to that of MoS₂ at the 660 nm excitation. τ_{X}=τ_{Y} 2 ps are the average exciton lifetimes, and Γₚ(d) is the TSD-dependent near-field excitation rate, given by

$${Γ}_{p} ( d ) = \{ \begin{matrix}A {( 1 - \frac{B}{{( R + d - c )}^{3}} )}^{- 2} , for d > 0.36 nm \\ 1 - {e}^{- \frac{d - c}{{d}_{p}}} , for c < d < 0.36 nm\end{matrix} , \qquad ( 8 )$$

where A is the constant of continuity, B=5028 characterizes the probe's material properties, R=10 nm is the radius of curvature of the apex of the tip 116, c=0.17 nm is the conductive ohmic contact distance, and dₚ=0.2 nm is the average quantum tunneling distance. Due to the heterojunction's intrinsic chemical potential difference, electrons transfer from WS₂ to MoS₂ (see arrow 120 in FIG. 1B) with the rate γ₁Γₚ(d), where γ₁ is the photoinduced electron transfer coefficient. Lastly, the parameter γ₂Γₚ(d) was introduced to describe the transfer of hot electrons from the plasmonic tip 116 to the resonantly excited heterojunction junction (arrow 122 in FIG. 1B) The hot electrons are injected with the rate of G_{HEI}Γ_{CT}(d) into the heterostructure and they relax by forming excitons at rates α or β in MoS₂ and WS₂, respectively, or through nonradiative decay channels at the rate of G_{HEI}Γ_{CT}(d).

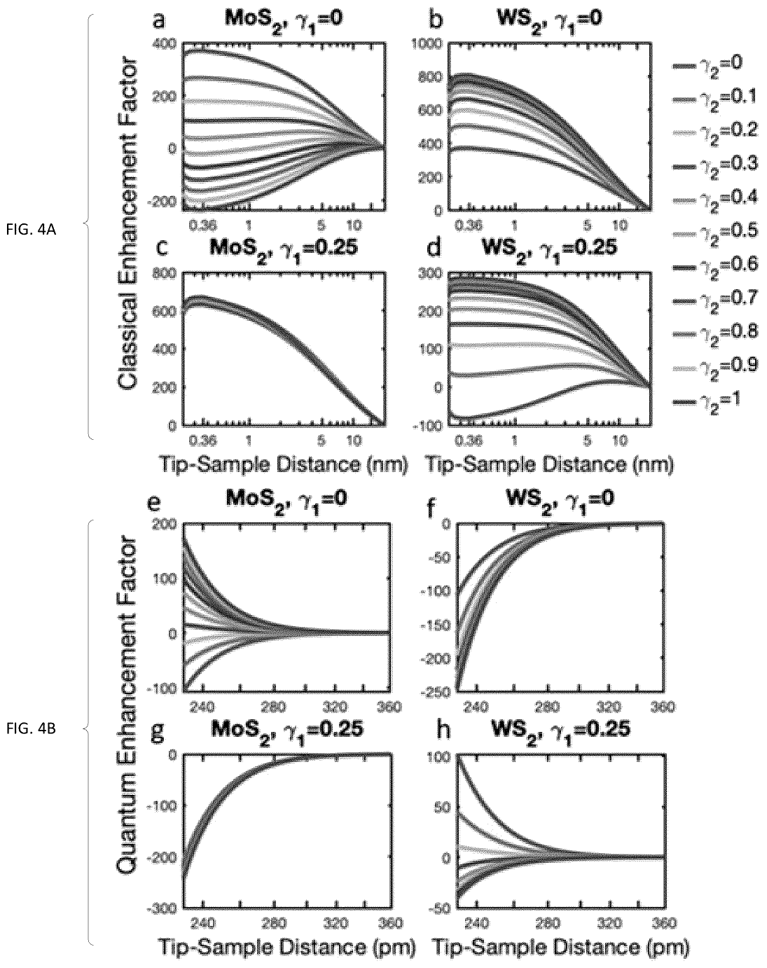

FIGS. 4A, 4B show the simulated PL enhancement factors for γ₁=0 (graph-windows a, b, e, f) and γ₁=0.25 (graph-windows c, d, g, h) for several values of γ₂. The classical and quantum EFs were obtained using the ratios of the |X [symbol] and |Y [symbol] state populations at the TSDs corresponding to the experimental EFs defined above. The PL signals for γ₁=γ₂=0 correspond to the pure MoS₂ (graph-windows a, e) and pure WS₂ (graph-windows b, f) materials located substantially outside the (width of) the heterojunction. In both cases, the EF values increase in the classical regime and decrease in the quantum regime (as shown in graph-windows a, b, e, and f of FIGS. 4A, 4B for γ₁=γ₂=0). This behavior corresponds to the traditional classical quantum plasmonics, and it is in good agreement with the experimental measurements at locations S1 (pure WS₂) and S5 (pure MoS₂), shown in graph-windows f, j of FIG. 2 and graph-windows f, j of FIG. 3. Graph-window j of FIG. 3 evidenced a small enhancement of PL at the WS₂ location due to the proximity to the junction, which disappears at locations S8 and S9 that are farther away from the junction.

### Discussion

In stark contradistinction with the studies provided by related art, the embodiments of the idea of the invention demonstrated that in heterostructures formed by chosen monolayer materials it is possible to obtain an additional increase of the PL signal in the tunneling regime beyond the conventional quantum plasmonic limit. The use approximately 660 nm excitation is near resonance with the tunneling-induced charge transfer plasmon (CTP) mode of the pico-sized cavity formed by the first and second pieces of the plasmonic material (here, by the Au tip 116 and the Au-substrate 120). The role of CTP resonance in the PL enhancement is confirmed by the comparison of the resonant 660 nm excitation, which gives the approximately 3 orders of magnitude PL enhancement (FIGS. 2 and 3) to the insignificant enhancement under the non-resonant 532 nm excitation (performed in a related embodiment, not shown here). The substantially monolayer 2D lateral heterostructure forms a p-n junction at the interface between the two monolayer materials due to the slightly different doping in these CVD-grown monolayer materials (with WS₂ being p-doped and MoS₂ being n-doped). This provided an additional mechanism of PL enhancement as shown in FIG. 1E. The space charge region at the heterojunction facilitated hot electron tunneling from the Au-tip to the positively charged MoS₂ portion of the heterostructure, while the transfer to the negatively charged WS₂ region was suppressed. The charge transfer to MoS₂ portion was increased by CTP in the quantum regime, thereby reducing the electric field of the depletion region and increasing the charge transfer γ₂ across the heterojunction. The resulting increased carrier concentration on WS₂ enhanced the PL signal.

The skilled artisan now readily appreciates that the quantum-tunneling-induced CTP and quantum plasmonic p-n junction mechanisms both contribute to the enhancement of PL from the WS₂ portion of the heterostructure (and to the suppression of the PL from the MoS₂ portion of the heterostructure) in the quantum regime. Here, the tunneling in a p-n junction placed inside the plasmonic picocavity is attributed to a charge-transfer-based chemical mechanism.

Understandably, embodiments of the invention can be utilized with the use of other 2D monolayer materials, such as to form the WSe₂—MoSe₂ heterostructure for example, by choosing the appropriate excitation source and plasmonic cavity formed by the first and second pieces of the plasmonic material.

The simulation illustrated in the graph-window d of FIG. 4A shows that WS₂ PL is enhanced at the junction as TSD is decreased in the classical regime only when γ₂>0.2, predicting the suppression of WS₂ PL for γ₂<0.2 in the classical regime. In addition, the graph-window h of FIG. 4B shows the decrease of the WS₂ PL at the heterojunction in the quantum regime for γ₂>0.3, which implies the optimal value of γ₂ of about 0.25. The constructed model, therefore, describes the significant contribution of the CTP resonant transfer, γ₂, the TSD dependence of which is opposite to that of the non-resonant charge transfer, γ₁. The interplay of these mechanisms determines the optimal values of the theoretical parameters that best describe the experimental observations.

While not expressly shown in the Figures, implementation of at least some of embodiments of the invention may require the use of a processor controlled by instructions stored in a memory—for example, for collection of optical data characterizing the operation of an apparatus of the invention. Such memory may be random access memory (RAM), read-only memory (ROM), flash memory or any other memory, or combination thereof, suitable for storing control software or other instructions and data. Those skilled in the art should also readily appreciate that instructions or programs defining the functions of the present invention may be delivered to a processor in many forms, including, but not limited to, information permanently stored on non-writable storage media (e.g. read-only memory devices within a computer, such as ROM, or devices readable by a computer I/O attachment, such as CD-ROM or DVD disks), information alterably stored on writable storage media (e.g. floppy disks, removable flash memory and hard drives) or information conveyed to a computer through communication media, including wired or wireless computer networks. In addition, while the invention may be embodied in software, the functions necessary to implement the invention may optionally or alternatively be embodied in part or in whole using firmware and/or hardware components, such as combinatorial logic, Application Specific Integrated Circuits (ASICs), Field-Programmable Gate Arrays (FPGAs) or other hardware or some combination of hardware, software and/or firmware components.

Understandably, a computer program product containing program code(s) embodying and/or governing the operation of at least one implementation of the idea of the invention remain within the scope of the invention.

For the purposes of this disclosure and the appended claims, the use of the terms “substantially”, “approximately”, “about” and similar terms in reference to a descriptor of a value, element, property or characteristic at hand is intended to emphasize that the value, element, property, or characteristic referred to, while not necessarily being exactly as stated, would nevertheless be considered, for practical purposes, as stated by a person of skill in the art. These terms, as applied to a specified characteristic or quality descriptor means “mostly”, “mainly”, “considerably”, “by and large”, “essentially”, “to great or significant extent”, “largely but not necessarily wholly the same” such as to reasonably denote language of approximation and describe the specified characteristic or descriptor so that its scope would be understood by a person of ordinary skill in the art. In one specific case, the terms “approximately”, “substantially”, and “about”, when used in reference to a numerical value, represent a range of plus or minus 20% with respect to the specified value, more preferably plus or minus 10%, even more preferably plus or minus 5%, most preferably plus or minus 2% with respect to the specified value. As a non-limiting example, two values being “substantially equal” to one another implies that the difference between the two values may be within the range of +/−20% of the value itself, preferably within the +/−10% range of the value itself, more preferably within the range of +/−5% of the value itself, and even more preferably within the range of +/−2% or less of the value itself.

The use of these terms in describing a chosen characteristic or concept neither implies nor provides any basis for indefiniteness and for adding a numerical limitation to the specified characteristic or descriptor. As understood by a skilled artisan, the practical deviation of the exact value or characteristic of such value, element, or property from that stated falls and may vary within a numerical range defined by an experimental measurement error that is typical when using a measurement method accepted in the art for such purposes. Other specific examples of the meaning of the terms “substantially”, “about”, and/or “approximately” as applied to different practical situations may have been provided elsewhere in this disclosure.

References throughout this specification to “one embodiment,” “an embodiment,” “a related embodiment,” or similar language mean that a particular feature, structure, or characteristic described in connection with the referred to “embodiment” is included in at least one embodiment of the present invention. Thus, appearances of the phrases “in one embodiment,” “in an embodiment,” and similar language throughout this specification may, but do not necessarily, all refer to the same embodiment. It is to be understood that no portion of disclosure, taken on its own and in possible connection with a figure, is intended to provide a complete description of all features of the invention.

For the purposes of this disclosure and the appended claims, the expression of the type “element A and/or element B” is defined to have the meaning that covers embodiments having element A alone, element B alone, or elements A and B taken together and, as such, is intended to be equivalent to “at least one of element A and element B”.

While the invention is described through the above-described specific non-limiting embodiments, it will be understood by those of ordinary skill in the art that modifications to, and variations of, the illustrated embodiments may be made without departing from the inventive concepts disclosed herein. The disclosed aspects may be combined in ways not listed above. Accordingly, the invention should not be viewed as being limited to the disclosed embodiment(s).

What is claimed is:

1. An article of manufacture comprising:
a substantially monolayer lateral two-dimensional (2D) heterostructure formed by first and second monolayer materials and having a 2D lateral heterojunction;
a first piece of a plasmonic material positioned at said heterojunction on one side of the heterostructure and a second piece of the plasmonic material positioned at said heterojunction on the other side of the heterostructure such as to be separated from one another by a distance substantially not exceeding 10 nanometers;
and
a source of excitation energy operably connected with the 2D lateral heterojunction and configured to excite said heterojunction with said energy resonantly with each of the monolayer materials.

2. An article of manufacture according to claim 1, configured as a source of light that contains first light with a first optical spectrum and second light with a second optical spectrum, the first optical spectrum representing a spectrum of photoluminescence of the first monolayer plasmonic material and the second optical spectrum representing a spectrum of photoluminescence of the second monolayer material.

3. An article of manufacture according to claim 1, further comprising a detection system that includes a detector and a spectral filter configured to substantially block excitation energy that has been produced by the source of excitation energy while, at the same time, to transmit first energy and second energy that are generated, respectively, at the first and second monolayer materials within the heterojunction when said heterojunction is irradiated with the excitation energy.

4. An article of manufacture according to claim 2, further comprising a detection system that includes a detector and a spectral filter configured to substantially block excitation energy that has been produced by the source of excitation energy while, at the same time, to transmit first energy and second energy that are generated, respectively, at the first and second monolayer materials within the heterojunction when said heterojunction is irradiated with the excitation energy.

5. An article of manufacture according to claim 1,
(5A) wherein a first cross-section of the first piece of the plasmonic material across an axis normal to a surface of said heterojunction substantially does not exceed a width of said heterojunction;
and/or
(5B) wherein a second cross-section of the second piece of the plasmonic material across the axis does not exceed said width;
and/or
(5C) wherein the first piece of the plasmonic material and/or the second piece of the plasmonic material is deposited on a corresponding surface of the heterojunction;
and/or
(5D) wherein the first piece of the plasmonic material and/or the second piece of the plasmonic material is dimensioned as a tip of a projecting object.

6. An article of manufacture according to claim 2,
(6A) wherein a first cross-section of the first piece of the plasmonic material across an axis normal to a surface of said heterojunction substantially does not exceed a width of said heterojunction;
and/or
(6B) wherein a second cross-section of the second piece of the plasmonic material across the axis does not exceed said width;
and/or
(6C) wherein the first piece of the plasmonic material and/or the second piece of the plasmonic material is deposited on a corresponding surface of the heterojunction;
and/or
(6D) wherein the first piece of the plasmonic material and/or the second piece of the plasmonic material is dimensioned as a tip of a projecting object.

7. An article of manufacture according to claim 4,
(7A) wherein a first cross-section of the first piece of the plasmonic material across an axis normal to a surface of said heterojunction substantially does not exceed a width of said heterojunction;
and/or
(7B) wherein a second cross-section of the second piece of the plasmonic material across the axis does not exceed said width;
and/or
(7C) wherein the first piece of the plasmonic material and/or the second piece of the plasmonic material is deposited on a corresponding surface of the heterojunction;
and/or
(7D) wherein the first piece of the plasmonic material and/or the second piece of the plasmonic material is dimensioned as a tip of a projecting object.

8. An article of manufacture according to claim 1, wherein the source of excitation energy includes a source of laser light.

9. A method for generating light, the method comprising:
with the use of the article of manufacture according to claim 1:
resonantly exciting at least the 2D lateral heterojunction of the substantially monolayer lateral 2D heterostructure with excitation energy produced by the source of excitation energy; and
generating first photoluminescent light at the 2D lateral heterojunction with the use of a tunneling-induced charge transfer plasmon (CTP) mode of the plasmonic material.

10. A method according to claim 9, further comprising:
when said irradiating includes irradiating a portion of at least one of the first and second monolayer materials that is outside of the 2D lateral heterojunction,
generating second photoluminescent light at said portion.

11. A method according to claim 9, further comprising:
substantially blocking the excitation energy from propagating from the heterostructure towards a chosen location while directing at least the first photoluminescent light to said chosen location.

12. A method according to claim 9, further comprising:
when an area of the at least one of the first and second monolayer materials that is outside of the 2D lateral heterojunction is also irradiated with the excitation energy,
repositioning at least one of the first and second pieces of the plasmonic material along a surface of the substantially monolayer lateral 2D heterostructure to vary an irradiance of photoluminescent light generated at the heterostructure by at least one order of magnitude when the at least one of the first and second pieces is moved between the heterojunction and said area,
wherein said repositioning includes maintaining a distance, measured between the first and second pieces along a normal to a surface of the heterostructure, substantially unchanged.

13. A method for generating light, the method comprising:
with the use of the article of manufacture according to claim 6:
resonantly exciting at least the 2D lateral heterojunction of the substantially monolayer lateral 2D heterostructure with excitation energy produced by the source of excitation energy; and
generating first photoluminescent light at the 2D lateral heterojunction with the use of a tunneling-induced charge transfer plasmon (CTP) mode of the plasmonic material.

14. A method according to claim 13, further comprising:
when said irradiating includes irradiating a portion of at least one of the first and second monolayer materials that is outside of the 2D lateral heterojunction,
generating second photoluminescent light at said portion.

15. A method according to claim 13, further comprising:
when an area of the at least one of the first and second monolayer materials that is outside of the 2D lateral heterojunction is also irradiated with the excitation energy,
repositioning at least one of the first and second pieces of the plasmonic material along a surface of the substantially monolayer lateral 2D heterostructure to vary an irradiance of photoluminescent light generated at the heterostructure by at least one order of magnitude when the at least one of the first and second pieces is moved between the heterojunction and said area,
wherein said repositioning includes maintaining a distance, measured between the first and second pieces along a normal to a surface of the heterostructure, substantially unchanged.

16. A method comprising:
increasing by at least one order of magnitude a first amount of first photoluminescent light, generated at a 2D lateral heterojunction of a substantially monolayer lateral 2D heterostructure formed by first and second monolayer materials as compared with a second amount of second photoluminescent light, generated at a portion of said heterostructure outside the 2D lateral heterojunction by:
sandwiching the 2D lateral heterojunction first piece of a plasmonic material positioned at said heterojunction on one side of the heterostructure and a second piece of the plasmonic material positioned at the heterojunction on the other side of the heterostructure such as to have a distance, separating the first and second pieces along a normal to a surface of the heterostructure to substantially not exceed 1 nanometer,
and
irradiating at least the 2D lateral heterojunction with light to excite each of the monolayer materials necessarily resonantly,
wherein said increasing is determined in comparison with a second amount of second photoluminescent light, generated at the 2D lateral heterojunction irradiated with said light in absence of said sandwiching.
